(19) United States
(12) Patent Application Publication
(10) Pub. No.: US 2022/0252973 A1
(43) Pub. Date: Aug. 11, 2022

(54) PELLICLE FOR EUV LITHOGRAPHY AND METHOD OF MANUFACTURING THE SAME

(71) Applicant: SK hynix Inc., Incheon-si Gyeonggi-do (KR)

(72) Inventor: Tae Joong HA, Icheon-si Gyeonggi-do (KR)

(73) Assignee: SK hynix Inc., Icheon-si Gyeonggi-do (KR)

(21) Appl. No.: 17/375,352

(22) Filed: Jul. 14, 2021

(30) Foreign Application Priority Data
Feb. 5, 2021 (KR) 10-2021-0017101

(51) Int. Cl. G03F 1/64; G03F 7/20; H01L 21/033

(52) U.S. Cl. CPC G03F 1/64; H01L 21/0337; H01L 21/0332; G03F 7/70983

(57) ABSTRACT

Disclosed is a pellicle for extreme ultraviolet (EUV) lithography and a method of manufacturing the same. The pellicle for EUV lithography includes a pellicle membrane including a plurality of through holes. The pellicle membrane includes a core layer and a protective layer that covers and protects the core layer. The frame supports the pellicle membrane.

### CROSS-REFERENCE TO RELATED APPLICATIONS

The present application claims priority under 35 U.S.C 119(a) to Korean Application No. 10-2021-0017101, filed on Feb. 5, 2021, which is incorporated herein by reference in its entirety.

### BACKGROUND

### 1. Technical Field

The present disclosure generally relates to lithography technology and, more particularly, to a pellicle for extreme ultraviolet (EUV) lithography and a method of manufacturing the same.

### 2. Related Art

With the development of lithography technology, semiconductor integrated circuits are becoming highly integrated. In order to implement a more refined line width, an EUV lithography technique that uses EUV light in a wavelength band of approximately 13.5 nm as exposure light is attracting attention. The EUV lithography technique employs a reflective photomask that reflects the EUV exposure light. The reflective photomask may be contaminated by particles or foreign substances so that attempts have been made to attach a pellicle to the reflective photomask.

In order to apply a pellicle to a reflective photomask that is used in the EUV lithography, mechanical and chemical durability, resistance to hydrogen plasma, and thermal resistance to the pellicle are relatively highly demanded. In addition, relatively high transmittance to EUV light is required for the pellicle.

### SUMMARY

An embodiment of the present disclosure may provide a pellicle for extreme ultraviolet (EUV) lithography including: a pellicle membrane including a core layer, a first protective layer that covers a first surface of the core layer, and through holes that are formed to penetrate the first protective layer; and a frame configured to support the pellicle membrane.

Another embodiment of the present disclosure may provide a pellicle for EUV lithography including: a pellicle membrane including a core layer and a protective layer, the protective layer covering and protecting the core layer, wherein through holes are formed to penetrate the core layer and the protective layer; and a frame supporting the pellicle membrane.

Yet another embodiment of the present disclosure may provide a method of manufacturing a pellicle for EUV lithography including: forming a core layer on a frame layer; forming through holes that penetrate the core layer; forming a frame that provides a cavity that is connected to the through holes by removing a portion of the frame layer; and forming a protective layer that covers a surface of the core layer.

Yet another embodiment of the present disclosure may provide a method of manufacturing a pellicle for EUV lithography including: forming a first protective layer on a frame layer; forming a core layer on the first protective layer; forming through holes that penetrate the core layer and the first protective layer; forming a second protective layer that extends to cover a surface of the core layer and inner sides of the through holes; and removing a portion of the frame layer to form a frame providing a cavity that is connected to the through holes.

Still yet another embodiment of the present disclosure may provide a method of manufacturing a pellicle for EUV lithography including: forming a first protective layer on a frame layer; forming a core layer on the first protective layer; forming a second protective layer on the core layer; forming through holes that penetrate the second protective layer, the core layer, and the first protective layer; forming a third protective layer pattern that covers inner sides of the through holes; and removing a portion of the frame layer to form a frame providing a cavity that is connected to the through holes.

### BRIEF DESCRIPTION OF THE DRAWINGS

FIGS. 1 to 4 are schematic views illustrating a pellicle for EUV lithography according to an embodiment of the present disclosure.

FIGS. 5 to 8 are schematic cross-sectional views illustrating a method of manufacturing a pellicle for EUV lithography according to an embodiment of the present disclosure.

FIGS. 9 to 15 are schematic cross-sectional views illustrating a method of manufacturing a pellicle for EUV lithography according to an embodiment of the present disclosure.

FIG. 16 is a schematic cross-sectional view illustrating a method of manufacturing a pellicle for EUV lithography according to an embodiment of the present disclosure.

FIGS. 17 to 20 are schematic cross-sectional views illustrating a method of manufacturing a pellicle for EUV lithography according to an embodiment of the present disclosure.

FIG. 21 is a schematic cross-sectional view illustrating a pellicle for EUV lithography according to an embodiment of the present disclosure.

### DETAILED DESCRIPTION

The terms used herein may correspond to words selected in consideration of their functions in presented embodiment of the present disclosures, and the meanings of the terms may be construed to be different according to ordinary skill in the art to which the embodiment of the present disclosures belong. If defined in detail, the terms may be construed according to the definitions. Unless otherwise defined, the terms (including technical and scientific terms) used herein have the same meaning as commonly understood by one of ordinary skill in the art to which the embodiment of the present disclosures belong.

In the description of the embodiments of the present disclosure, descriptions such as “first” and “second,” “upper” and “lower,” and “left” and “right” are for distinguishing members, and are not used to limit the members themselves or to mean a specific order, but to refer to relative positional relationships, and do not limit the specific case in which the member is directly in contact or another member is further introduced into the interface between them. The same interpretation may be applied to other expressions describing the relationship between components.

The embodiments of the present disclosure may be applied to a technical field for implementing integrated circuits such as dynamic random access memory (DRAM) devices, phase change random access memory (PcRAM) devices, or resistive random access memory (ReRAM) devices. In addition, the embodiments of the present disclosure may be applied to a technical field of implementing memory devices such as static random access memory (SRAM) devices, NAND-type flash memory devices, NOR-type flash memory devices, magnetic random access memory (MRAM) devices, or ferroelectric random access memory (FeRAM) devices, or logic devices in which integrated logic circuits are integrated. The embodiments of the present disclosure may be applied to a technical field for implementing various products requiring fine patterns.

Same reference numerals refer to same devices throughout the specification. Even though a reference numeral might not be mentioned or described with reference to a drawing, the reference numeral may be mentioned or described with reference to another drawing. In addition, even though a reference numeral might not be shown in a drawing, it may be described with reference another drawing.

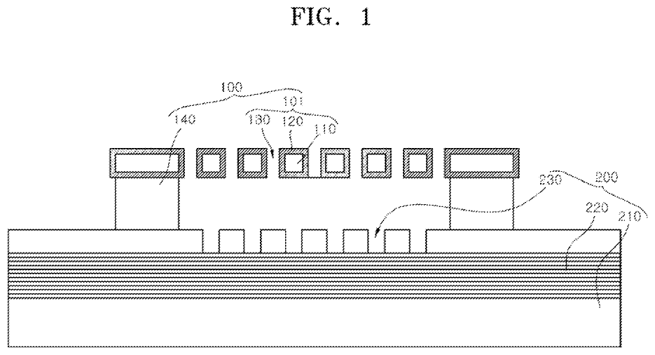

FIG. 1 is a schematic cross-sectional view illustrating a photomask 200 to which a pellicle 100 for EUV lithography is assembled according to an embodiment of the present disclosure.

Referring to FIG. 1, the pellicle 100 may be assembled on the photomask 200 and may be used in an EUV lithography process. The photomask 200 may be configured as a reflective mask structure that is used in an EUV lithography process. The photomask 200 may include a mirror layer 220 and a light absorber pattern 230, which are formed on a substrate 210. The mirror layer 220 may be configured as a structure that reflects EUV light. The light absorber pattern 230 may be configured as a pattern that provides an image shape to be transferred through an EUV lithography process.

The pellicle 100, according to an embodiment, may be coupled to the photomask 200 to prevent and protect the mirror layer 220 and the light absorber pattern 230 from being damaged by hydrogen plasma. The pellicle 100 may substantially prevent and protect the mirror layer 220 and the light absorber pattern 230 of the photomask 200 from being contaminated by contaminants, such as particles.

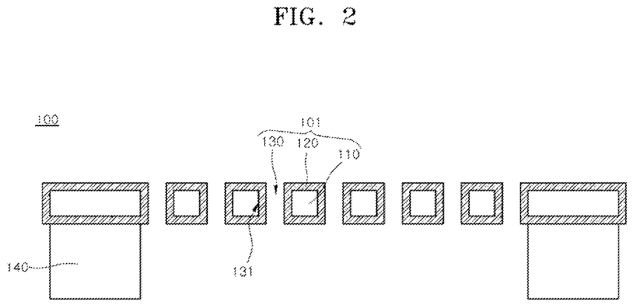

FIG. 2 is a schematic cross-sectional view illustrating the enlarged pellicle 100 in FIG. 1.

Referring to FIGS. 1 and 2, the pellicle 100, according to an embodiment, may have a porous pellicle structure. The pellicle 100 may have a structure in which a pellicle membrane 101 and a frame 140 are assembled. The pellicle membrane 101 may be a member that protects the mirror layer 220 and the light absorber pattern 230 of the photomask 200. The frame 140 may be an assembly member that supports the pellicle membrane 101 and couples the pellicle membrane 101 to the photomask 200.

The pellicle membrane 101 may include a plurality of through holes 130. The pellicle membrane 101 may include a core layer 110 and a protective layer 120 that covers and protects the core layer 110. The protective layer 120 and the core layer 110 may constitute the pellicle membrane 101 so that the through holes 130 vertically penetrate the pellicle membrane 101. The core layer 110 may be disposed in a shape of a film that provides the plurality of through holes 130. The protective layer 120 may be disposed in a shape of a coating layer that covers a surface of the core layer 110. The protective layer 120 may extend to cover the surface of the core layer 110 and to cover and protect inner sides 131 of the through holes 130.

The through holes 130 may be arranged in a honeycomb shape, a checkerboard pattern shape, a square shape, or a diamond shape in a plan view.

The protective layer 120 may include a different material compared to the core layer 110. The protective layer 120 may be introduced as a layer that adds additional mechanical strength to the core layer 110. The protective layer 120 may be introduced as a layer that additionally adds chemical resistance, resistance to hydrogen plasma, and thermal durability to the core layer 110. The protective layer 120 may include a material with a relatively higher mechanical strength than the material that constitutes the core layer 110.

The protective layer 120 may include a material with a relatively higher chemical resistance than the material that constitutes the core layer 110. The protective layer 120 may include a material with relatively higher resistance to hydrogen plasma than the material that constitutes the core layer 110. The protective layer 120 may include a material with relatively higher thermal conductivity or higher thermal durability than a material constituting the core layer 110.

The protective layer 120 may include silicon nitride (SiN). The protective layer 120 may include silicon oxynitride (SiON), silicon oxide (SiO₂), molybdenum silicon oxide (MoSi₂O), molybdenum silicon nitride (MoSi₂N), molybdenum silicon oxynitride (MoSiON), ruthenium (Ru), or molybdenum (Mo). The core layer 110 may include silicon carbide (SiC). The core layer 110 may include silicon (Si), silicon oxycarbide (SiCO), silicon carbon nitride (SiCN), silicon oxycarbon nitride (SiCON), amorphous carbon (C), graphene, carbon nanotubes (CNT), molybdenum (Mo) silicide, boron carbide (B₄C), or zirconium (Zr).

Referring to FIG. 2 again, the pellicle membrane 101 may be formed to have a thickness of several tens of nm. The pellicle membrane 101 may be formed to have a thickness of 30 nm to 50 nm. In a state in which the through holes 130 are not formed, the pellicle membrane may be configured to have transmittance of about 90% with respect to EUV light. As the through holes 130 are formed in the pellicle membrane 101, the porous pellicle membrane 101 with the through holes 130 may achieve transmittance of 92% to 97%. The through holes 130 may serve to increase the transmittance of the pellicle membrane.

Each of the through holes 130 may have a diameter of approximately 5 nm to 200 nm. Furthermore, each of the through holes 130 may have a diameter of approximately 20 nm to 30 nm. If the diameter of each of the through holes 130 is 30 nm, the space between the through holes 130 may be 60 nm, and the transmittance of the pellicle membrane itself may be 90%, the porous pellicle membrane 101 with the through holes 130 achieving transmittance of approximately 92%. The space between the through holes may be determined by measuring from the center of one through hole to the center of the next nearest through hole. If one through hole is further arranged for every four through holes to reduce the space between the through holes 130 to ½*sin 45°*60 nm, that is, about 25.5 nm, the transmittance of the porous pellicle membrane 101 with the through holes 130 may be increased to approximately 94%.

If the diameter of the through hole 130 is 30 nm, the space between the through holes 130 may be 45 nm, and the transmittance of the pellicle membrane itself may be 90%, the porous pellicle membrane 101 with the through holes 130 achieving a transmittance of approximately 93.5%. If the space between the through holes 130 is reduced to ½*sin 45°*45 nm, that is, about 19.2 nm, the transmittance of the porous pellicle membrane 101 with the through holes 130 may be increased to about 97%. In this way, by arranging the through holes 130 to be spaced apart from each other by approximately 19 nm to 60 nm, the transmittance of the pellicle membrane 101 may be increased from 90% to approximately 92% to 97%.

If each of the through holes 130 has a diameter of approximately 30 nm, the porous pellicle membrane 101 may filter out particles with a diameter of 30 nm or more. Because the particles with a diameter of 30 nm or more cannot pass through the through holes 130, the mirror layer (220 in FIG. 1) and the light absorber pattern (230 in FIG. 1) of the photomask (200 in FIG. 1) are not contaminated from the particles. If the through holes 130 with a diameter of approximately 30 nm are arranged to be spaced apart from each other by 60 nm, the probability that the particles with a diameter of 20 nm pass through the through holes 130 may be only approximately 2.2%. If the through holes 130 with a diameter of approximately 30 nm are arranged to be spaced apart from each other by 45 nm, the probability that the particles with a diameter of 20 nm pass through the through holes 130 may be only approximately 3.9%. In this way, even though the through holes 130 are provided in the pellicle membrane 101, the probability that the particles pass through the through holes 130 and contaminate the mirror layer (220 in FIG. 1) and the light absorber pattern (230 in FIG. 1) of the photomask (200 in FIG. 1) may be limited very low.

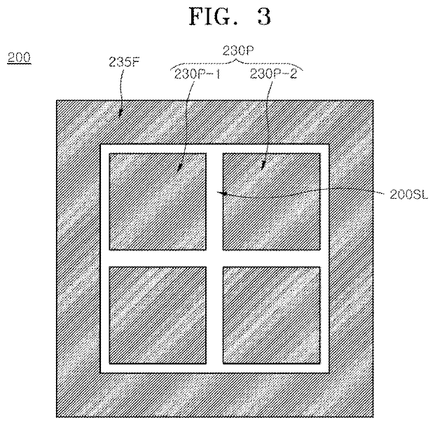

FIG. 3 is a schematic plan view illustrating detailed regions of the photomask 200 of FIG. 1.

Referring to FIGS. 1 and 3, the photomask 200 may have a shape of a substrate with a rectangular plane or a square plane. The photomask 200 may include a frame region 235F of an edge portion and a field region 230P inside the frame region 235F. The field region 230P may include first field regions 230P-1 and second field regions 230P-2, which are separated from each other. The light absorber patterns 230 may be disposed in the first field regions 230P-1 and the second field regions 230P-2. A scribe lane region 200SL may be disposed between the first field region 230P-1 and the second field region 230P-2, and the first field regions 230P-1 and the second field regions 230P-2 may be distinguished from each other by the scribe lane region 200SL. The field region 230P may include a plurality of detailed field regions such as the first field region 230P-1 and the second field region 230P-2. The scribe lane region 200SL may separate the frame region 235F and the field region 230P.

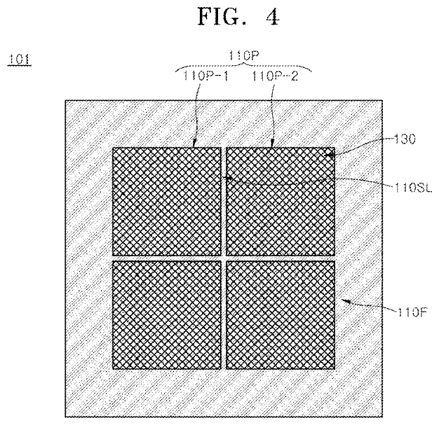

FIG. 4 is a schematic plan view illustrating a planar shape of the pellicle membrane 101 in FIG. 1.

Referring to FIGS. 1 and 4, the pellicle membrane 101 may include a frame region 110F of an edge portion and a field region 110P inside the frame region 110F. The field region 110P may include first field regions 110P-1 and second field regions 110P-2 which are separated from each other. Through holes 130 may be disposed in the first field regions 110P-1 and the second field regions 110P-2. A scribe lane region 110SL may be disposed between the first field regions 110P-1 and the second field regions 110P-2, and the first field region 110P-1 and the second field region 110P-2 may be distinguished from each other by the scribe lane region 110SL. The field region 110P may include a plurality of detailed field regions such as the first field regions 110P-1 and the second field regions 110P-2. The scribe lane region 110SL may separate the frame region 110F and the field region 110P.

Referring to FIGS. 3 and 4, the first field regions 110P-1, the second field regions 110P-2, and the scribe lane region 110SL of the pellicle membrane 101 may be regions overlapping with and corresponding to the first field regions 230P-1, the second field regions 230P-2, and the scribe lane region 200SL of the photomask 200, respectively. Because the light absorber patterns (230 in FIG. 1) are not disposed in the scribe lane region 200SL of the photomask 200, the scribe lane region 110SL of the pellicle membrane 101 may be a region in which it is not required to increase the transmittance of EUV light. Accordingly, the through holes 130 might not be disposed in the scribe lane region 110SL of the pellicle membrane 101, thereby increasing the mechanical strength of the pellicle membrane 101. The scribe lane region 110SL may have a width of approximately several μm to several hundred μm.

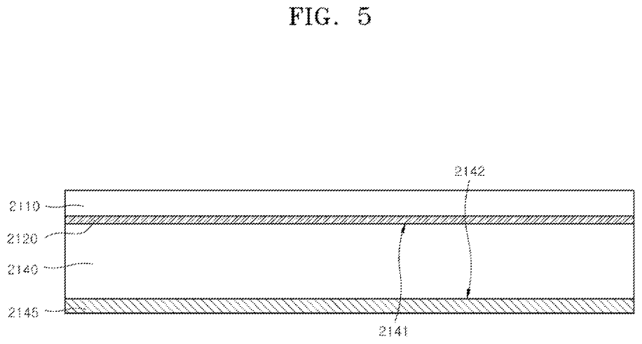

FIGS. 5 to 8 are schematic cross-sectional views illustrating a method of manufacturing a pellicle for EUV lithography according to an embodiment of the present disclosure.

Referring to FIG. 5, a core layer 2110 of a pellicle membrane may be formed on a frame layer 2140. The frame layer 2140 may be introduced as a substrate such as a silicon (Si) wafer. The frame layer 2140 may have a first surface 2141 and a second surface 2142 that is on the opposite side of the first surface 2141. The core layer 2110 may be deposited on the first surface 2141 of the frame layer 2140. The core layer 2110 may be formed to have a thickness of approximately 5 nm to 40 nm. The core layer 2110 may be formed to have a thickness of about 30 nm.

Before the core layer 2110 is deposited, a masking layer 2145 that covers the second surface 2142 of the frame layer 2140 may be formed. The masking layer 2145 may be deposited as a layer of a material with etch selectivity with respect to a silicon (Si) wafer, such as silicon nitride (SiN).

A sacrificial layer 2120 may be further formed between the core layer 2110 and the frame layer 2140. The sacrificial layer 2120 may include a layer of a different material compared to the core layer 2110 and the frame layer 2140. The sacrificial layer 2120 may include silicon oxide (SiO₂). The sacrificial layer 2120 may include silicon nitride (SiN). The sacrificial layer 2120 may serve to protect the core layer 2110 from damage in a subsequent process of patterning the frame layer 2140. The sacrificial layer 2120 may be formed to have a thickness of approximately 2 nm to 10 nm.

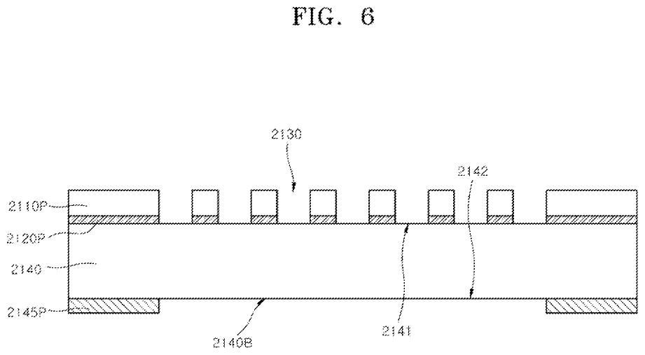

Referring to FIGS. 5 and 6, a plurality of through holes 2130 penetrating the core layer 2110P may be formed. By selectively etching away some portions of the core layer 2110, the core layer 2110P in which the through holes 2130 are formed may be formed. In order to perform a selective etching process to the core layer 2110, resist coating, exposure, and development may be performed to form a first photoresist pattern (not illustrated) on the core layer 2110. A selective etching process that uses the first photoresist pattern as an etch mask may be performed to the core layer 2110 to form the core layer 2110P in which the through holes 2130 are formed. Thereafter, the core layer 2110P may be cleaned. The through holes 2130 may extend to penetrate the sacrificial layer 2120P that is located under the core layer 2110P.

A portion of the masking layer 2145 may be selectively removed to form a mask pattern 2145P. The mask pattern 2145P may be formed to expose a portion 2140B of the second surface 2142 of the frame layer 2140. Resist coating, exposure, and development may be performed to form a second photoresist pattern (not illustrated) on the masking layer 2145, and a selective etching process that uses the second photoresist pattern as an etch mask may be performed to pattern the mask pattern 2145P.

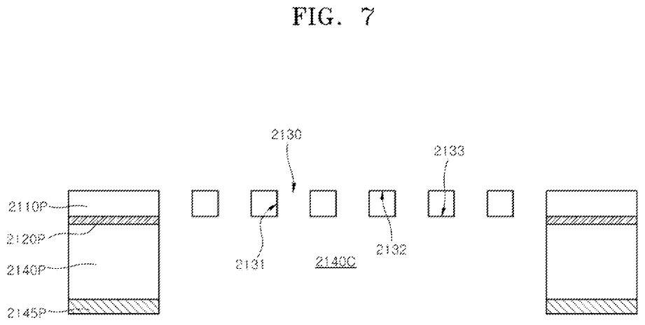

Referring to FIGS. 6 and 7, a portion of the frame layer 2140 may be removed to form a frame 2140P that provides a cavity 2140C that is connected to the through holes 2130. The cavity 2140C may overlap with regions in which the through holes 2130 of the core layer 2110P are distributed. A portion 2140B of the frame layer 2140 that is exposed by the mask pattern 2145P may be selectively removed from the second surface 2142 of the frame layer 2140 to form the cavity 2140C exposing a bottom surface 2133 of the core layer 2110P.

The portion 2140B of the frame layer 2140 may be etched away through a wet etching process by using a potassium hydroxide (KOH) solution. The sacrificial layer 2120P may substantially prevent the core layer 2110P from being damaged during the wet etching process by using a potassium hydroxide (KOH) solution. Some portions of the sacrificial layer 2120P that overlap with the cavity 2140C may be removed through an additional etching process that is performed after the etching process for forming the cavity 2140C. Some portions of the sacrificial layer 2120P may be etched away through a wet etching process by using a hydrogen fluoride (HF) solution.

As the cavity 2140C is formed, the bottom surface 2133 that is on the opposite side of a top surface 2132 of the core layer 2110P may be exposed. Side surfaces of the core layer 2110P that provide inner sides 2131 of the through holes 2130 may also be exposed.

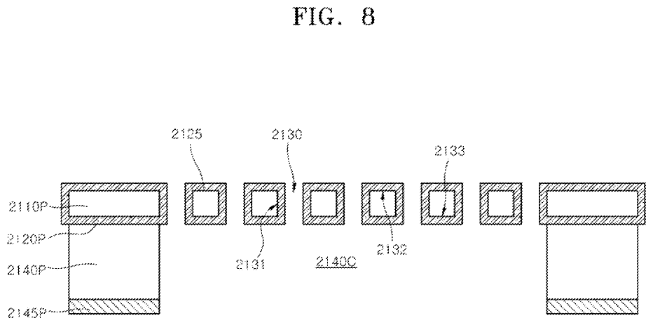

Referring to FIGS. 7 and 8, a protective layer 2125 that covers the surface of the core layer 2110P may be formed. The protective layer 2125 may extend to cover the top surface 2132 and the bottom surface 2133 of the core layer 2110P and may also cover the inner sides 2131 of the through holes 2130. The protective layer 2125 may be deposited to cover the surface of the core layer 2110P without completely filling the through holes 2130. The protective layer 2125 may be formed to have a thickness of approximately 2 nm to 10 nm.

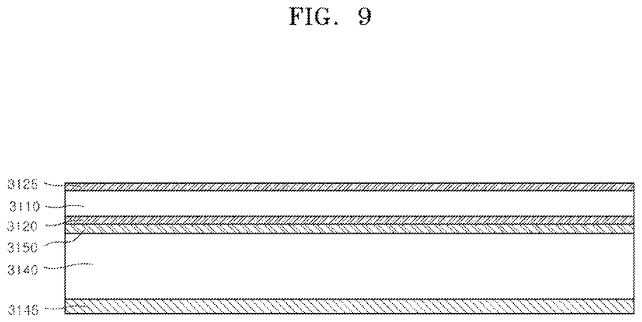

FIGS. 9 to 15 are schematic cross-sectional views illustrating a method of manufacturing a pellicle for EUV lithography according to an embodiment of the present disclosure.

Referring to FIG. 9, a first protective layer 3120 may be formed on a first surface of a frame layer 3140. The first protective layer 3120 may be formed as a layer that constitutes a portion of the protective layer 120 of the pellicle membrane 101 in FIG. 1. The first protective layer 3120 may be formed to have a thickness of approximately 2 nm to 10 nm. A core layer 3110 of a pellicle membrane may be formed on the first protective layer 3120. The frame layer 3140 may be introduced as a substrate, such as a silicon (Si) wafer. The core layer 3110 may be formed to have a thickness of approximately 5 nm to 40 nm.

Before the core layer 3110 is deposited, a masking layer 3145 may be further formed to cover a second surface of the frame layer 3140 that is on the opposite side of the first surface of the frame layer 3140. A first sacrificial layer 3150 may be further formed between the first protective layer 3120 and the frame layer 3140. The first sacrificial layer 3150 may include a different material compared to materials that constitute the core layer 3110, the first protective layer 3120, and the frame layer 3140. The first sacrificial layer 3150 may include silicon oxide (SiO₂). The first sacrificial layer 3150 may be formed to have a thickness of approximately 2 nm to 10 nm.

A second protective layer 3125 may be further formed on the core layer 3110. The second protective layer 3125 may be formed as a layer that constitutes another portion of the protective layer 120 of the pellicle membrane 101 in FIG. 1. The second protective layer 3125 may be formed to have a thickness of approximately 2 nm to 50 nm. Each of the first and second protective layers 3120 and 3125 may be deposited as a layer of a material that constitutes the protective layer 120 in FIG. 1. The first and second protective layers 3120 and 3125 may be deposited as layers of the same material or may be deposited as layers of different materials.

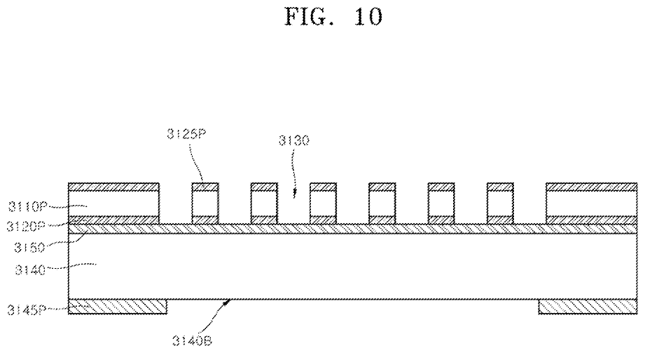

Referring to FIGS. 9 and 10, a plurality of through holes 3130 that penetrate the second protective layer 3125P, the core layer 3110P, and the first protective layer 3120P may be formed. Some portions of the second protective layer 3125, the core layer 3110, and the first protective layer 3120 may be sequentially and selectively etched away to form a stack structure of the second protective layer 3125P, the core layer 3110P, and the first protective layer 3120P, which provides the through holes 3130. In order to sequentially etch the second protective layer 3125, the core layer 3110, and the first protective layer 3120, resist coating, exposure, and development may be performed to form a first photoresist pattern (not illustrated) on the second protective layer 3125. By performing a selective etching process that uses the first photoresist pattern as an etch mask, the stack structure of the second protective layer 3125P, the core layer 3110P, and the first protective layer 3120P in which the through holes 3130 are formed may be patterned. Thereafter, the stack structure of the core layer 3110P and the first protective layer 3120P may be cleaned. The through holes 3130 may be formed to expose some portions of the first sacrificial layer 3150 that are located under the first protective layer 3120P.

A portion of the masking layer 3145 may be selectively removed to form a mask pattern 3145P. The mask pattern 3145P may be formed to expose a portion 3140B of a bottom surface of the frame layer 3140. Resist coating, exposure, and development may be performed to form a second photoresist pattern (not illustrated) on the masking layer 3145, and a selective etching process may be performed to form the mask pattern 3145P.

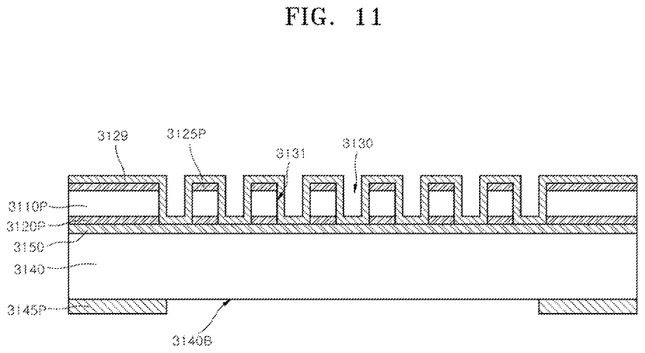

Referring to FIGS. 10 and 11, a third protective layer 3129 may be formed to conformally cover the stack structure of the second protective layer 3125P, the core layer 3110P, and the first protective layer 3120P. The third protective layer 3129 may extend to cover and protect the surface of the stack structure of the second protective layer 3125P, the core layer 3110P, and the first protective layer 3120P. A portion of the third protective layer 3129 may be introduced to constitute another portion of the protective layer 120 of the pellicle membrane 101 in FIG. 1. The third protective layer 3129 may be formed to have a thickness of approximately 2 nm to 10 nm. Because a portion of the third protective layer 3129 extends along the shapes of the through holes 3130, a portion of the third protective layer 3129 may extend to cover a portion of the first sacrificial layer 3150 that is exposed at the bottom of each of the through holes 3130. Accordingly, some portions of the third protective layer 3129 may provide concave shapes that follow the shapes of the through holes 3130.

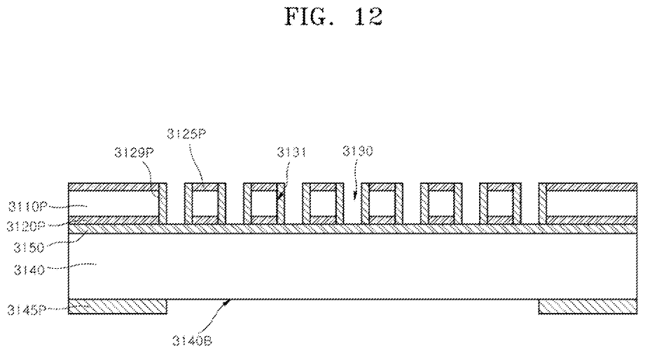

Referring to FIGS. 11 and 12, an anisotropic dry etching process may be performed with respect to the third protective layer 3129. Through the anisotropic etching process, portions of the third protective layer 3129 that cover the second protective layer 3125P and portions of the third protective layer 3129 that cover the bottoms of the through holes 3130 may be selectively removed. As some portions of the third protective layer 3129 are selectively removed, third protective layer patterns 3129P that cover the inner sides 3131 of the through holes 3130 may be formed in the through holes 3130. The third protective layer patterns 3129P may constitute the protective layer 120 in FIG. 1, together with the first protective layer 3120P and the second protective layer 3125P.

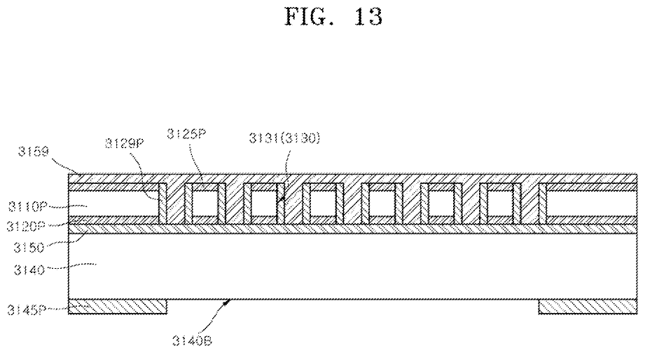

Referring to FIGS. 13 and 12, a second sacrificial layer 3159 may be further formed. The second sacrificial layer 3159 may be deposited to cover the third protective layer patterns 3129P and the second protective layer 3125P to protect the third protective layer patterns 3129P and the second protective layer 3125P from an external environment or a subsequent process. The second sacrificial layer 3159 may be formed of substantially the same material as the first sacrificial layer 3150. The second sacrificial layer 3159 may be formed of or may include silicon oxide (SiO₂). The second sacrificial layer 3159 may be formed to fill the through holes 3130.

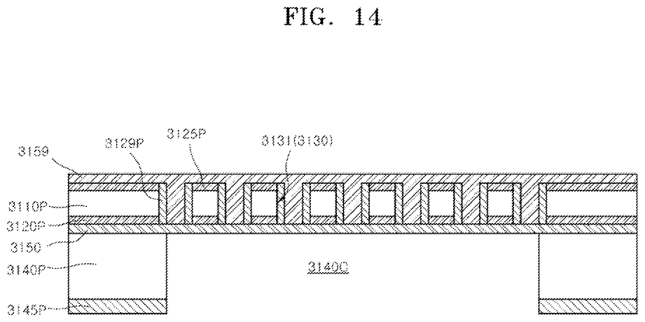

Referring to FIGS. 14 and 13, a portion of the frame layer 3140 may be removed to form a frame 3140P that provides a cavity 3140C. The cavity 3140C may overlap with regions of the core layer 3110P in which the through holes 3130 are distributed. A portion 3140B of the frame layer 3140 that is exposed by the mask pattern 3145P may be etched. The portion 3140B of the frame layer 3140 may be etched away through a wet etching process by using a potassium hydroxide (KOH) solution. The first sacrificial layer 3150 and the second sacrificial layer 3159 may serve to protect the third protective layer patterns 3129P, the second protective layer 3125P, and the first protective layer 3120P from the wet etching. Accordingly, the core layer 3110P, the third protective layer patterns 3129P, the second protective layer 3125P, and the first protective layer 3120P may be effectively prevented from being damaged by the wet etching by using a potassium hydroxide (KOH) solution.

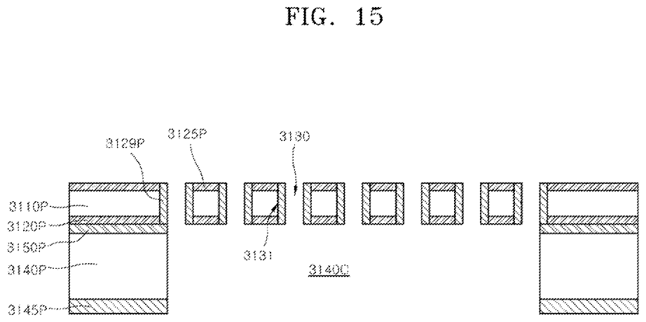

Referring to FIGS. 15 and 14, after patterning the frame 3140P providing the cavity 3140C, a portion of the first sacrificial layer 3150 exposed to the cavity 3140C may be removed. The second sacrificial layer 3159 may also be selectively removed. A wet etching process that uses a hydrogen fluoride (HF) solution may be performed to a portion of the first sacrificial layer 3150 exposed to the cavity 3140C and a portion of the second sacrificial layer 3159 so that the portion of the first sacrificial layer 3150 that is exposed to the cavity 3140C and the portion of the second sacrificial layer 3159 may be selectively removed. As the first sacrificial layer 3150 is removed, the cavity 3140C of the frame 3140P may be connected to the through holes 3130.

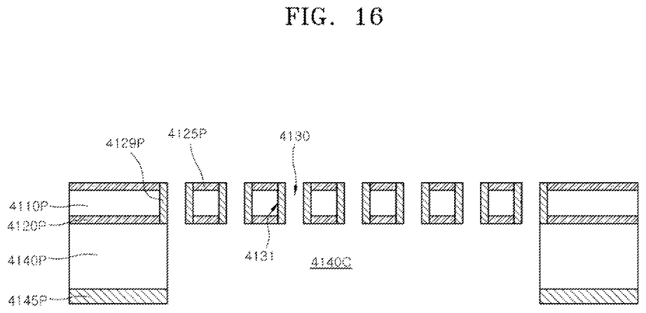

FIG. 16 is a schematic cross-sectional view illustrating a method of manufacturing a pellicle for EUV lithography according to an embodiment of the present disclosure.

Referring to FIG. 16 together with FIGS. 14 and 15, the process steps of the method of manufacturing a pellicle described with reference to FIGS. 9 to 15 may be performed while omitting the first sacrificial layer 3150 and the second sacrificial layer 3159. As a result of performing those process steps, a pellicle structure in which a core layer 4110P is supported by a frame 4140P, providing a cavity 4140C, the core layer 4110P providing through holes 4130, and a first protective layer 4120P, a second protective layer 4125P, and third protective layer patterns 4129P protecting the core layer 4110P may be implemented. The third protective layer patterns 4129P may cover and protect inner sides 4131 of the through holes 4130. A mask pattern 4145P may be formed to cover a bottom surface of the frame 4140P.

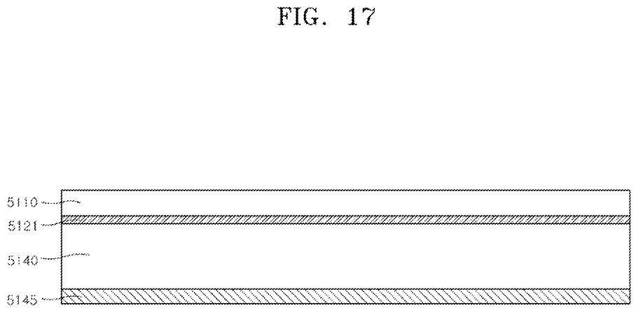

FIGS. 17 to 20 are schematic cross-sectional views illustrating a method of manufacturing a pellicle for EUV lithography according to an embodiment of the present disclosure.

Referring to FIG. 17, a first protective layer 5121 may be formed on a first surface of a frame layer 5140. The first protective layer 5121 may be formed as a layer that constitutes a portion of the protective layer 120 of the pellicle membrane 101 in FIG. 1. The first protective layer 5121 may be formed to have a thickness of approximately 2 nm to 10 nm. A core layer 5110 of a pellicle membrane may be formed on the first protective layer 5121. The core layer 5110 may be formed to have a thickness of approximately 5 nm to 40 nm. Before the core layer 5110 is deposited, a masking layer 5145 may be further formed to cover a second surface of the frame layer 5140 that is on the opposite side of the first surface of the frame layer 5140.

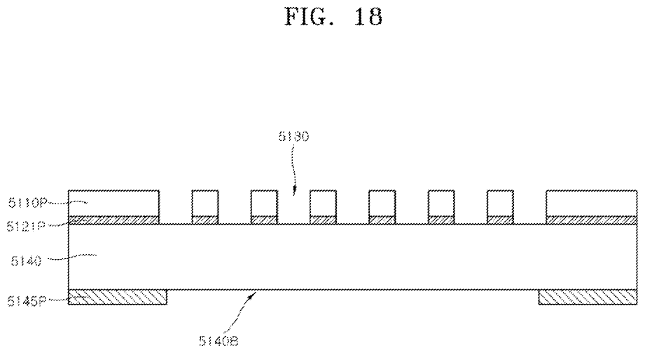

Referring to FIGS. 17 and 18, a plurality of through holes 5130 that penetrate the core layer 5110P and the first protective layer 5121P may be formed. Some portions of the core layer 5110 and the first protective layer 5121 may be sequentially and selectively etched away to form a stack structure of the core layer 5110P and the first protective layer 5121P, which provides the through holes 5130. In order to sequentially etch the core layer 5110 and the first protective layer 5121, resist coating, exposure, and development may be performed to form a first photoresist pattern (not illustrated) on the core layer 5110. By performing a selective etching process that uses the first photoresist pattern as an etch mask, the stack structure of the core layer 5110P and the first protective layer 5121P in which the through holes 5130 are formed may be formed. Thereafter, the stack structure of the core layer 5110P and the first protective layer 5121P may be cleaned. The through holes 5130 may be formed to expose a portion of the frame layer 5140 that is positioned under the first protective layer 5121P.

A portion of the masking layer 5145 may be selectively removed to form a mask pattern 5145P. The mask pattern 5145P may be patterned to expose a portion 5140B of the bottom surface of the frame layer 5140. Resist coating, exposure, and development may be performed to form a second photoresist pattern (not illustrated) on the masking layer 5145, and a selective etching process that uses the second photoresist pattern as an etch mask may be performed to pattern the mask pattern 5145P.

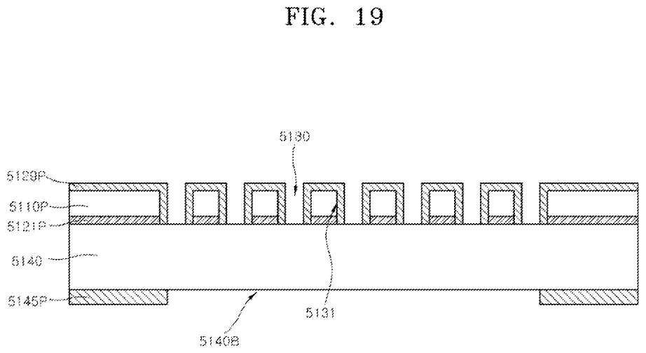

Referring to FIGS. 18 and 19, a second protective layer 5129P may be formed to conformally cover the stack structure of the core layer 5110P and the first protective layer 5121P. The second protective layer 5129P may extend to cover and protect a surface of the stack structure of the core layer 5110P and the first protective layer 5121P. The second protective layer 5129P may be selectively deposited only on the exposed surfaces of the core layer 5110P and the first protective layer 5121P to expose portions of the frame layer 5140 at the bottoms of the through holes 5130. The second protective layer 5129P may extend to cover a top surface of the core layer 5110P and inner sides 5131 of the through holes 5130. The first protective layer 5121P and the second protective layer 5129P may be layers that constitute the protective layer 120 of the pellicle membrane 101 in FIG. 1.

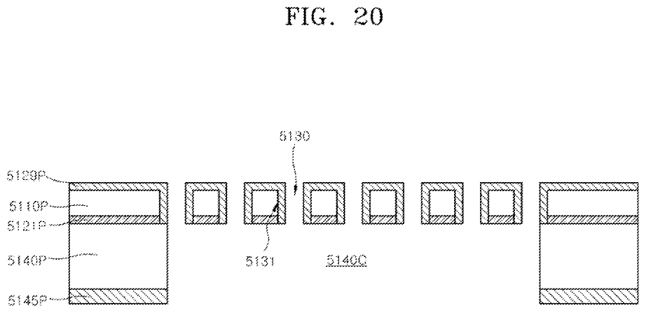

Referring to FIGS. 19 and 20, a portion of the frame layer 5140 may be removed to form a frame 5140P that provides a cavity 5140C. The cavity 5140C may be formed to be connected to the through holes 5130.

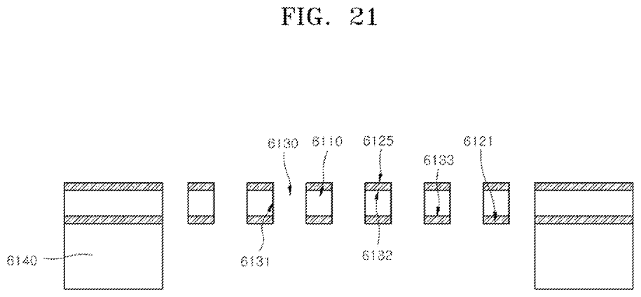

FIG. 21 is a schematic cross-sectional view illustrating a pellicle 6100 for EUV lithography according to an embodiment of the present disclosure.

Referring to FIG. 21, the pellicle 6100 may include a pellicle membrane 6101 with through holes 6130. A structure of the pellicle membrane 6101 may include a core layer 6110 and a first protective layer 6125. The through holes 6130 may be formed to penetrate the core layer 6110 and the first protective layer 6125 by selectively etching away some portions of the core layer 6110 and the first protective layer 6125

The first protective layer 6125 may be formed to cover a first surface 6132 of the core layer 6110. The first surface 6132 of the core layer 6110 may be a top surface of the core layer 6110, and a second surface 6133 may be on the opposite side of the first surface 6132, the bottom surface of the core layer 6110. Before forming the through holes 6130, a second protective layer 6121 that covers the second surface 6133 of the core layer 6110 may be further formed. The second protective layer 6121 may be formed on the frame layer to be patterned into a frame 6140, the core layer 6110 may be formed on the second protective layer 6121, and the first protective layer 6125 may be formed on the core layer 6110, sequentially. The first and second protective layers 6125 and 6121 may be formed to overlap with each other on and under the core layer 6110 so that the pellicle membrane 6101 structure may be configured as a sandwich panel structure. Thereafter, the through holes 6130 may be formed to penetrate the first protective layer 6125, the core layer 6110, and the second protective layer 6121. The through holes 6130 may penetrate the first protective layer 6125 and the core layer 6110, and the through holes 6130 may extend to further penetrate the underlying second protective layer 6121. The first and second protective layers 6125 and 6121 might not cover the inner sides 6131 of the through holes 6130 so that the inner sides 6131 of the through holes 6130 may be exposed.

The inventive concept has been disclosed in conjunction with some embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all of distinctive features in the equivalent scope should be construed as being included in the inventive concept.

What is claimed is:

1. A pellicle for extreme ultraviolet (EUV) lithography comprising:
a pellicle membrane configured to include a core layer and a protective layer, the protective layer covering and protecting the core layer, wherein through holes are formed to penetrate the core layer and the protective layer; and
a frame configured to support the pellicle membrane.

2. The pellicle for EUV lithography of claim 1, wherein the protective layer extends to cover inner sides of the through holes.

3. The pellicle for EUV lithography of claim 1, wherein the pellicle membrane includes:
first and second field regions spaced apart from each other in which the through holes are arranged; and
a scribe lane region located between the first and second field regions in which the through holes are not arranged.

4. The pellicle for EUV lithography of claim 3, wherein the scribe lane region has a width of several μm to several hundred μm.

5. The pellicle for EUV lithography of claim 1, wherein each of the through holes has a diameter of 5 nm to 200 nm.

6. The pellicle for EUV lithography of claim 1, wherein the through holes are arranged to be spaced apart from each other by 19 nm to 60 nm.

7. The pellicle for EUV lithography of claim 1, wherein the through holes are arranged in a honeycomb shape, a checkerboard pattern shape, a square shape, or a diamond shape on a plane.

8. The pellicle for EUV lithography of claim 1, wherein the protective layer includes a different material compared to the core layer.

9. The pellicle for EUV lithography of claim 1, wherein the core layer includes one of silicon (Si), silicon carbide (SiC), silicon oxycarbide (SiCO), silicon carbon nitride (SiCN), silicon oxycarbon nitride (SiCON), amorphous carbon (C), graphene, carbon nanotubes (CNT), molybdenum (Mo) silicide, boron carbide (B₄C), and zirconium (Zr).

10. The pellicle for EUV lithography of claim 1, wherein the protective layer includes of silicon nitride (SiN), silicon oxynitride (SiON), silicon oxide (SiO₂), molybdenum silicon oxide (MoSi₂O), molybdenum silicon nitride (MoSi₂N), molybdenum silicon oxynitride (MoSiON), ruthenium (Ru), and molybdenum (Mo).

11. A pellicle for extreme ultraviolet (EUV) lithography comprising:
a pellicle membrane including a core layer, a first protective layer that covers a first surface of the core layer and through holes that are formed to penetrate the first protective layer; and
a frame supporting the pellicle membrane.

12. The pellicle for EUV lithography of claim 11,
wherein the pellicle membrane further includes a second protective layer that covers a second surface that is on an opposite side of the first surface of the core layer, and
wherein the through holes extend to further penetrate the second protective layer.

13. A method of manufacturing a pellicle for extreme ultraviolet (EUV) lithography, the method comprising:
forming a core layer on a frame layer;
forming through holes that penetrate the core layer;
forming a frame that provides a cavity that is connected to the through holes by removing a portion of the frame layer; and
forming a protective layer that covers a surface of the core layer.

14. The method of claim 13, wherein the frame layer includes a silicon (Si) wafer.

15. The method of claim 13, wherein the protective layer extends to cover inner sides of the through holes.

16. The method of claim 13,
wherein the frame layer includes a first surface and a second surface that is on an opposite side of the first surface,
wherein the core layer is formed on the first surface of the frame layer, and
wherein forming the frame includes:
forming a masking layer that covers the second surface of the frame layer;
selectively removing a portion of the masking layer to form a mask pattern that exposes a portion of the second surface of the frame layer; and
etching a portion of the second surface of the frame layer that is exposed by the mask pattern.

17. A method of manufacturing a pellicle for extreme ultraviolet (EUV) lithography, the method comprising:
forming a first protective layer on a frame layer;
forming a core layer on the first protective layer;
forming through holes that penetrate the core layer and the first protective layer;
forming a second protective layer that extends to cover a surface of the core layer and inner sides of the through holes; and
removing a portion of the frame layer to form a frame that provides a cavity that is connected to the through holes.

18. A method of manufacturing pellicle for extreme ultraviolet (EUV) lithography, the method comprising:
forming a first protective layer on a frame layer;
forming a core layer on the first protective layer;
forming a second protective layer on the core layer;
forming through holes that penetrate the second protective layer, the core layer, and the first protective layer;
forming a third protective layer pattern that covers inner sides of the through holes; and
removing a portion of the frame layer to form a frame that provides a cavity that is connected to the through holes.

19. The method of claim 18, wherein forming the third protective layer pattern includes:
forming a third protective layer that extends to cover the second protective layer and bottoms of the through holes; and
selectively removing a portion of the third protective layer that covers the second protective layer and a portion that covers the bottoms of the through holes.

20. The method of claim 18, further comprising forming a first sacrificial layer between the frame layer and the first protective layer.

21. The method of claim 20, further comprising forming a second sacrificial layer that protects the second protective layer and the third protective layer pattern while filling the through holes.

22. The method of claim 21, further comprising removing the first and second sacrificial layers after forming the frame.
